(19) United States
(12) Patent Application Publication
(10) Pub. No.: US 2026/0181810 A1
(43) Pub. Date: Jun. 25, 2026

(54) COMPUTE SERVER

(71) Applicant: Douyin Vision Co., Ltd., Beijing (CN)

(72) Inventors: Shifeng WANG, Beijing (CN); Xiaojun GAO, Beijing (CN); Peng WANG, Beijing (CN); An WANG, Beijing (CN); Zhibo ZHAO, Beijing (CN); Xin WANG, Beijing (CN); Yuanlin REN, Beijing (CN); Jian WANG, Beijing (CN)

(21) Appl. No.: 19/359,096

(22) Filed: Oct. 15, 2025

(30) Foreign Application Priority Data
Dec. 23, 2024 (CN) 202411907951.7

(51) Int. Cl. H05K 7/14; H05K 7/20

(52) U.S. Cl. CPC H05K 7/1489; H05K 7/1492; H05K 7/20727

(57) ABSTRACT

The present disclosure discloses a compute server, which includes a chassis, at least two node modules, a network interface card, and a power supply mechanism. The at least two node modules are sequentially arranged along a first direction. The node modules are slidably disposed in the chassis along a second direction, and a first connector and a second connector are disposed at an end of each node module along the second direction. The network interface card is disposed in the chassis, and is provided with at least two flexible connectors. The at least two flexible connectors are in a one-to-one correspondence with the at least two node modules, and each flexible connector is connected to a corresponding first connector. The power supply mechanism is disposed in the chassis, and is electrically connected to the network interface card. At least two connection ports are provided in the power supply mechanism.

### CROSS-REFERENCE TO RELATED APPLICATION

This application claims the priority to and benefits of the Chinese Patent Application, No. 202411907951.7, which was filed on Dec. 23, 2024. The aforementioned patent application is hereby incorporated by reference in its entirety.

### TECHNICAL FIELD

The present disclosure relates to the technical field of servers, and in particular, to a compute server.

### BACKGROUND

With the widespread popularization of Internet and cloud computing technologies, data centers have entered a period of rapid growth. During this period, the number of cores of a mainstream general-purpose compute central processing unit (CPU) has been increasing. To manage resources more effectively and simplify a scheduling process, a general-purpose computer type with a single-path design is gradually becoming the preferred choice in the market. Meanwhile, the current mainstream network has been generally upgraded to a high-speed transmission standard of 100 G or 200 G, which, although bringing a significant performance improvement, has also made the network cost relatively high.

In a single-path system environment, configuring each system with a multi-port network interface card (NIC) separately often leads to waste of network bandwidth. Therefore, a more reasonable approach is to use a multi-port NIC to connect multiple single-path systems according to an actual network requirement. This may ensure that a system performance meets a service requirement and effectively optimize costs.

However, in the current system, multiple nodes are directly connected to a NIC through cables in the same server. Although this design simplifies hardware deployment to some extent, it brings great maintenance challenges. Once a single-path node needs to be maintained, all other single-path nodes have to be taken offline at the same time due to a close association between the nodes, which seriously interferes with normal operation of a service.

### SUMMARY

In view of this, the present disclosure provides a compute server to solve the problem that once a single-path node needs to be maintained, all other single-path nodes have to be taken offline at the same time due to a close association between the nodes, which seriously interferes with normal operation of a service.

The present disclosure provides a compute server, including: a chassis, at least two node modules, a network interface card, and a power supply mechanism. The at least two node modules are sequentially arranged along a first direction; the node modules are slidably disposed in the chassis along a second direction, and a first connector and a second connector are disposed at an end of each node module along the second direction; the network interface card is disposed in the chassis, and is provided with at least two flexible connectors; the at least two flexible connectors are in a one-to-one correspondence with the at least two node modules, and each flexible connector is connected to a corresponding first connector; the power supply mechanism is disposed in the chassis, and is electrically connected to the network interface card; at least two connection ports are provided in the power supply mechanism; the at least two connection ports are in a one-to-one correspondence with the at least two node modules, and the second connectors are in plug-in connection with the corresponding connection ports; and the first direction is perpendicular to the second direction.

### BRIEF DESCRIPTION OF DRAWINGS

In order to more clearly explain the technical solutions in the specific embodiments of the present disclosure or in the related art, the following will briefly introduce the drawings that need to be used in the description of the specific embodiments or related art. Obviously, the drawings in the following description are some implementations of the present disclosure. For those of ordinary skill in the art, other drawings may be obtained based on these drawings without creative efforts.

FIG. 1 is a schematic diagram of an overall structure of a compute server according to an embodiment of the present disclosure;

FIG. 2 is an exploded structure diagram of the compute server according to the embodiment of the present disclosure; and

FIG. 3 is a schematic plan view of FIG. 2.

Description of reference numerals in the drawings:

1: chassis; 101: separator; 1011: avoidance slot; 2: node module; 201: first connector; 202: second connector; 203: protrusion; 3: network interface card; 301: flexible connector; 302: connection wire; 4: power supply mechanism; 401: power backboard; 402: power module; 5: heat dissipation mechanism; 501: fan backboard; 502: fan module; 6: second power wire; and 7: second signal wire.

### DETAILED DESCRIPTION

In order to make the purpose, technical solutions and advantages of the embodiments of the present disclosure clearer, the technical solutions in the embodiments of the present disclosure will be clearly and completely described below in conjunction with the drawings in the embodiments of the present disclosure. Obviously, the described embodiments are part of the embodiments of the present disclosure, but not all of them. Based on the embodiments in the present disclosure, all other embodiments obtained by those skilled in the art without creative efforts belong to the protection scope of the present disclosure.

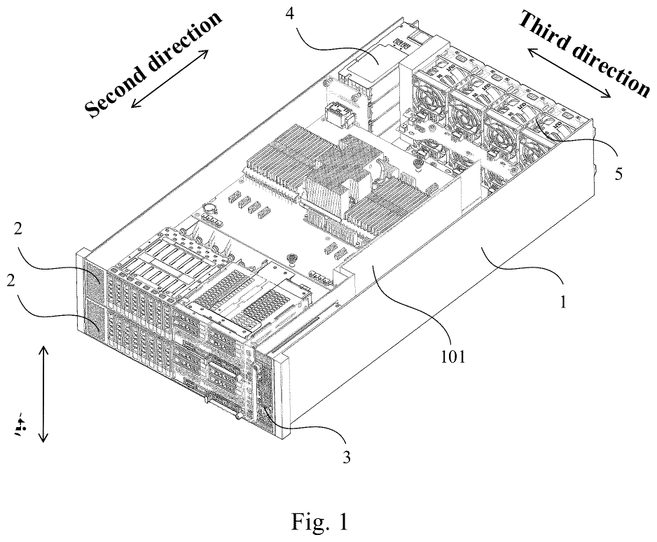

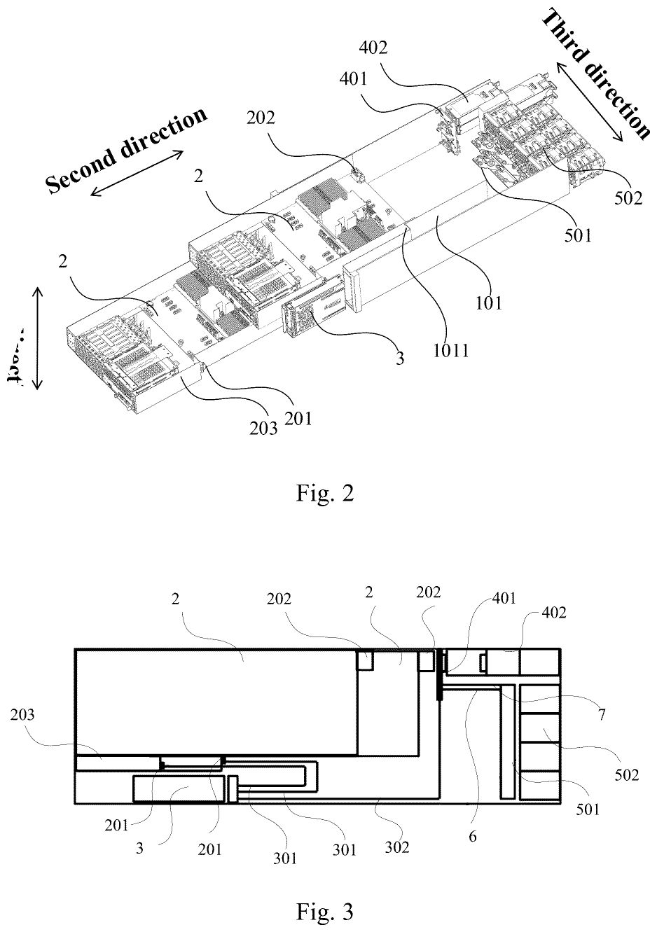

The embodiments of the present disclosure are described below in conjunction with FIG. 1 to FIG. 3.

According to an embodiment of the present disclosure, a compute server is provided, which includes a chassis 1, at least two node modules 2, a network interface card 3, and a power supply mechanism 4; the at least two node modules 2 are sequentially arranged along a first direction; the node modules 2 are slidably disposed in the chassis 1 along a second direction, and a first connector 201 and a second connector 202 are provided at an end of the node module 2 along the second direction; the network interface card 3 is disposed in the chassis 1 and is provided with at least two flexible connectors 301; the at least two flexible connectors 301 are in a one-to-one correspondence with the at least two node modules 2, and each flexible connector 301 is connected with a corresponding first connector 201; the power supply mechanism 4 is disposed in the chassis 1 and is electrically connected with the network interface card 3; at least two connection ports are provided on the power supply mechanism 4; the at least two connection ports are in a one-to-one correspondence with the at least two node modules 2, and the second connectors 202 are in plug-in connection with the corresponding connection ports; and the first direction is perpendicular to the second direction.

Since the network interface card 3 is provided with the at least two flexible connectors 301, the at least two flexible connectors 301 are in a one-to-one correspondence with the at least two node modules 2, the power supply mechanism 4 is provided with the at least two connection ports, and the at least two connection ports are in a one-to-one correspondence with the at least two node modules 2, the sharing of a network and power supply by the plurality of node modules 2 is realized; and since the node modules 2 are slidably disposed in the chassis 1 along the second direction, and both the first connector 201 and the second connector 202 are disposed at the end of the node module 2 along the second direction, when a certain node module 2 needs to be repaired due to a failure, the node module 2 is pulled out along the second direction, so that the first connector 201 and the second connector 202 may be separated from the corresponding flexible connector 301 and the corresponding connection port, and the node module 2 may be taken off the shelf for repair without affecting the normal operation of other node modules 2; and thus, when a certain node module 2 is repaired, other node modules 2 may continue to work, thereby significantly reducing the offline duration of the server during maintenance and effectively improving the overall utilization of the server.

In an embodiment, the first connector 201 is in plug-in connection with the flexible connector 301.

Since the first connector 201 is in plug-in connection with the flexible connector 301, when the node module 2 that has failed is taken out of the chassis 1, the first connector 201 is separated from the flexible connector 301, so that the node module 2 may be completely taken off the shelf.

In a specific implementation, the flexible connector 301 is a first signal wire.

In an embodiment, the first connector 201 is a blind mating connector.

Since the first connector 201 adopts a blind mating connector design, the connection process is more convenient and faster, and a stable connection between the node module 2 and the network interface card 3 may be realized without precise alignment, which not only improves the connection efficiency, but also reduces the risk of connection failure caused by alignment errors, thereby ensuring the stability and reliability of the connection between the node module 2 and the network interface card 3.

In an embodiment, a separator 101 is provided in the chassis 1, the node module 2 and the network interface card 3 are respectively disposed on two sides of the separator 101 along a third direction, and the third direction is perpendicular to each of the first direction and the second direction.

The node module 2 and the network interface card 3 are physically separated by the separator 101, which not only effectively avoids possible electromagnetic interference between the node module 2 and the network interface card 3, and ensures the stability and reliability of the system operation, but also, when the node module 2 is subjected to plugging and unplugging maintenance operations, the separator 101 also plays an isolation role, preventing direct contact between the node module 2 and the network interface card 3, thereby avoiding potential damage caused by friction interference, prolonging the service life of the node module 2 and the network interface card 3, and improving the durability of the overall system.

Preferably, slide rails are provided on side walls of both the separator 101 and the chassis 1, the slide rails extend along the second direction, two sides of each node module 2 along the third direction are respectively in sliding connection with two slide rails, and the slide rails may not only define a sliding path and direction of the node module 2 in the chassis 1, but also support the node module 2, so that the plurality of node modules 2 may be kept in a mutually independent and stable state in the chassis 1, and when a node module 2 with a failure is plugged or unplugged, the possibility of scratching or collision between the node module 2 and an adjacent node module 2 is reduced, and the safety and integrity of all node modules 2 are further ensured; moreover, when the node module 2 located below needs to be pulled out for maintenance or replacement, the node module 2 located above may remain stable due to the supporting effect of the slide rails, and the risk of accidental falling is effectively avoided.

In an embodiment, a side of the node module 2 close to the network interface card 3 is provided with a protrusion 203, and the first connector 201 is disposed on a side of the protrusion 203 close to the power supply mechanism 4; and a side of the separator 101 close to the node module 2 is provided with an avoidance slot 1011, the protrusion 203 is located in the avoidance slot 1011, a slot wall of the avoidance slot 1011 close to the power supply mechanism 4 is provided with a through hole, and the flexible connector 301 passes through the through hole to be connected with the first connector 201.

By arranging the first connector 201 on the protrusion 203 and arranging the protrusion 203 in the avoidance slot 1011, it is not only convenient for the flexible connector 301 to be quickly and accurately butted with the first connector 201, but also the physical connection distance between the first connector 201 and the network interface card 3 may be effectively shortened, thereby avoiding unnecessary waste of the flexible connector 301 caused by an excessively long connection line, and ensuring the compactness and stability of the entire connection structure.

In an implementation of the embodiment, one through hole is provided, and the through hole is a long-strip-shaped hole extending along the first direction.

In another implementation of the embodiment, at least two through holes are provided, and the at least two through holes are in a one-to-one correspondence with the at least two flexible connectors 301.

In an embodiment, the power supply mechanism 4 includes a power backboard 401 and a power module 402, the power module 402 and the node modules 2 are respectively disposed on two sides of the power backboard 401 along the second direction, and the power module 402 is connected with the power backboard 401; and the connection port is disposed on the power backboard 401, and the second connector 202 is in plug-in connection with the connection port.

Since the power module 402 and the node modules 2 are respectively located on different sides of the power backboard 401, the power module 402 and the node modules 2 do not interfere with each other when being installed or disassembled, thereby greatly improving the maintenance convenience and system flexibility, not only optimizing the space utilization, but also ensuring the stability and reliability of the system operation of the server.

In a specific implementation, multiple power modules 402 are provided, the multiple power modules 402 are sequentially arranged along the first direction, and the multiple power modules 402 are all connected to the power backboard 401.

In an implementation of the embodiment, the power module 402 is connected to the power backboard 401 through a connector in a plug-in manner; in another implementation of the embodiment, the power module 402 is connected to the power backboard 401 through a cable.

In an embodiment, the second connector 202 is a blind mating connector.

Since the second connector 202 adopts a blind mating connector design, the connection process is more convenient and faster, and a stable connection between the node modules 2 and the power supply mechanism 4 may be realized without precise alignment, which not only improves the connection efficiency, but also reduces the risk of connection failure caused by alignment errors, thereby ensuring the stability and reliability of the connection between the node modules 2 and the power supply mechanism 4.

In an embodiment, the power backboard 401 is electrically connected to the network interface card 3 through a connection wire 302.

Through the disposal of the connection wire 302, a stable and efficient electrical connection between the power backboard 401 and the network interface card 3 is realized, ensuring the smoothness and stability of the operation of the entire server system.

Specifically, the connection wire 302 is a first power wire.

In an embodiment, the compute server further includes a heat dissipation mechanism 5, the heat dissipation mechanism 5 is disposed on a side of the node modules 2 close to the power supply mechanism 4, and the heat dissipation mechanism 5 is disposed in the chassis 1 and electrically connected to the power backboard 401.

Since the heat dissipation mechanism 5 is disposed on the side of the node module 2 close to the power supply mechanism 4, the mutual independence of the heat dissipation mechanism 5 and the node module 2 in the installation and disassembly processes is ensured, and mutual interference is avoided; at the same time, the heat dissipation mechanism 5 may efficiently cover and serve the plurality of node modules 2, thereby realizing the sharing of cooling resources; not only the space layout is optimized and the heat dissipation efficiency is improved, but also all node modules 2 may be ensured to operate in a stable and suitable temperature environment, thereby improving the performance and prolonging the overall service life.

In an embodiment, the heat dissipation mechanism 5 includes a fan backboard 501 and a fan module 502, the fan backboard 501 is disposed between the fan module 502 and the node module 2, and the fan backboard 501 is disposed in parallel with the second direction; and the fan module 502 and the power backboard 401 are both connected with the fan backboard 501.

Since the fan backboard 501 is disposed in parallel with the second direction, the fan module 502 may be prevented from being shielded, smooth flow of air between the fan module 502 and the node module 2 is ensured, and heat generated by the node module 2 may be effectively taken away, so that the node module 2 is kept operating in a suitable working temperature range, which not only optimizes the structural layout of the heat dissipation mechanism 5, but also significantly improves the heat dissipation efficiency of the node module 2, ensuring the stability and reliability of the system.

In a specific implementation, a baffle is disposed between the fan module 502 and the power module 402, and the fan module 502 and the power module 402 are respectively disposed on two sides of the baffle along the third direction. The fan module 502 and the power module 402 are physically separated by the baffle, which not only effectively avoids possible electromagnetic interference between the fan module 502 and the power module 402, but also prevents direct contact between the fan module 502 and the power module 402, and when the fan module 502 or the power module 402 is subjected to plugging and unplugging maintenance, potential damage caused by friction interference between the fan module 502 and the power module 402 is avoided, thereby prolonging the service life of the fan module 502 or the power module 402.

In a specific implementation, multiple heat dissipation mechanisms 5 are provided, the multiple heat dissipation mechanisms 5 are sequentially arranged along the first direction, and the multiple heat dissipation mechanisms 5 are all connected to the power backboard 401.

Preferably, each heat dissipation mechanisms 5 establishes a signal connection with a node module 2. When a certain node module 2 fails and needs to be repaired, the node module 2 is first disconnected from the power backboard 401, and then the power backboard 401 stops supplying power to the heat dissipation mechanism 5 corresponding to the node module 2 with the failure, thus ensuring that when the number of node modules 2 inside the server is reduced and the heat dissipation demand is reduced accordingly, the cooling capacity is also reduced accordingly, thereby realizing effective energy saving and avoiding unnecessary power waste.

In a specific implementation, the fan backboard 501 is electrically connected to the power backboard 401 through a second power wire 6, and is connected to the power backboard 401 through a second signal wire 7 for signal connection.

In a specific implementation, the fan module 502 includes a plurality of fan units sequentially disposed along the third direction, and each fan unit is connected to the fan backboard 501.

In an implementation of the embodiment, the fan backboard 501 is disposed perpendicular to the first direction, and each fan unit is connected to the fan backboard 501 through a connector in a plug-in manner, or each fan unit is connected to the fan backboard 501 through a cable.

In another implementation of the embodiment, the fan backboard 501 is disposed perpendicular to the third direction, and each fan unit is connected to the fan backboard 501 through a cable.

Although the embodiments of the present disclosure are described in conjunction with the drawings, those skilled in the art may make various modifications and variations without departing from the spirit and scope of the present disclosure, and such modifications and variations fall within the scope defined by the appended claims.

1. A compute server, comprising:
a chassis;
at least two node modules sequentially arranged along a first direction, wherein the node modules are slidably disposed in the chassis along a second direction, and a first connector and a second connector are disposed at an end of each node module along the second direction;
a network interface card disposed in the chassis and provided with at least two flexible connectors, wherein the at least two flexible connectors are in a one-to-one correspondence with the at least two node modules, and each flexible connector is connected to a corresponding first connector; and
a power supply mechanism disposed in the chassis and electrically connected to the network interface card, wherein at least two connection ports are provided in the power supply mechanism, the at least two connection ports are in a one-to-one correspondence with the at least two node modules, and the second connector is in plug-in connection with a corresponding connection ports; and the first direction is perpendicular to the second direction.

2. The compute server of claim 1, wherein the first connector is in plug-in connection with the flexible connector.

3. The compute server of claim 2, wherein the first connector is a blind mating connector.

4. The compute server of claim 1, wherein a separator is disposed in the chassis, the node modules and the network interface card are respectively disposed on two sides of the separator along a third direction, and the third direction is perpendicular to each of the first direction and the second direction.

5. The compute server of claim 4, wherein a side of the node modules close to the network interface card is provided with a protrusion, and the first connector is disposed on a side of the protrusion close to the power supply mechanism; and a side of the separator close to the node modules is provided with an avoidance slot, the protrusion is located in the avoidance slot, a slot wall of the avoidance slot close to the power supply mechanism is provided with a through hole, and the flexible connector passes through the through hole to be connected to the first connector.

6. The compute server of claim 1, wherein the power supply mechanism comprises a power backboard and a power module, the power module and the node modules are respectively disposed on two sides of the power backboard along the second direction, and the power module is connected to the power backboard; and the connection ports are disposed on the power backboard, and the second connector is in plug-in connection with a connection port.

7. The compute server of claim 6, wherein the second connector is a blind mating connector.

8. The compute server of claim 6, wherein the power backboard is electrically connected to the network interface card through a connection wire.

9. The compute server of claim 6, further comprising a heat dissipation mechanism, wherein the heat dissipation mechanism is disposed on a side of the node modules close to the power supply mechanism, and the heat dissipation mechanism is disposed in the chassis and electrically connected to the power backboard.

10. The compute server of claim 9, wherein the heat dissipation mechanism comprises a fan backboard and a fan module, the fan backboard is disposed between the fan module and the node modules, and the fan backboard is disposed in parallel with the second direction; and the fan module and the power backboard are both connected to the fan backboard.
